(19) United States
(12) Patent Application Publication
(10) Pub. No.: US 2026/0147031 A1
(43) Pub. Date: May 28, 2026

(54) SEMICONDUCTOR TEST DEVICE AND SEMICONDUCTOR WAFER

(71) Applicant: HUNAN SAN'AN SEMICONDUCTOR CO., LTD., Changsha (CN)

(72) Inventors: Zhonglin Han, Changsha (CN); Yu Yang, Changsha (CN); Wei Xie, Changsha (CN); Yiqing Wu, Changsha (CN)

(21) Appl. No.: 19/381,703

(22) Filed: Nov. 6, 2025

(30) Foreign Application Priority Data
Nov. 25, 2024 (CN) 202411698316.2

(51) Int. Cl. G01R 31/26; H10D 84/83

(52) U.S. Cl. CPC G01R 31/2621; H10D 84/835

(57) ABSTRACT

A semiconductor test device and a semiconductor wafer are provided. A first doping region includes a first sub-doped region, a second sub-doped region and a third sub-doped region. The third sub-doped region is connected to the first sub-doped region and the second sub-doped region spaced. A second doped region includes a fourth sub-doped region and a fifth sub-doped region. The fourth sub-doped region and the fifth sub-doped region are respectively arranged in the first sub-doped region and the second sub-doped region. A gate structure is at least partially arranged above the third sub-doped region. A second conductive electrode is connected to the fourth sub-doped region in ohmic contact. A third conductive electrode is connected to the fifth sub-doped region in ohmic contact.

### TECHNICAL FIELD

The disclosure relates to a semiconductor test device and a semiconductor wafer.

### BACKGROUND

Accurate characterization of carrier mobility in power devices is critical for device performance optimization. However, test structures in the related art may have limitations in terms of complexity, cost, or measurement accuracy. There is a need for improved test devices capable of providing reliable mobility characterization.

### SUMMARY

Specifically, according to some embodiments, a semiconductor test device includes: a substrate, an epitaxial layer, a first doped region, a second doped region, a third doped region, a gate structure, a second conductive electrode, and a third conductive electrode.

The epitaxial layer is arranged on a surface of the substrate, and the substrate and the epitaxial layer are of a first conductivity type.

The first doped region includes a first sub-doped region, a second sub-doped region and a third sub-doped region. The first sub-doped region, the second sub-doped region and the third sub-doped region are all arranged in the epitaxial layer and extend from a surface of the epitaxial layer facing away from the substrate along a first direction; the first direction is a direction of the epitaxial layer facing towards the substrate. The first doped region is of a second conductivity type. The first sub-doped region and the second sub-doped region are spaced along a second direction, the third sub-doped region is connected to the first sub-doped region and the second sub-doped region, and the second direction is perpendicular to the first direction.

The second doped region includes a fourth sub-doped region and a fifth sub-doped region. The fourth sub-doped region is arranged in the first sub-doped region and has a first spacing distance from an edge of the first sub-doped region. The fifth sub-doped region is arranged in the second sub-doped region and has a second spacing distance from an edge of the second sub-doped region. The fourth sub-doped region and the fifth sub-doped region extend from the epitaxial layer facing away from the surface of the substrate along the first direction. The second doped region is of the first conductivity type. The first spacing distance is the same as the second spacing distance. A width of the third sub-doped region is greater than or equal to the first spacing distance and less than or equal to twice the first spacing distance. A width direction of the third sub-doped region is perpendicular to the first direction and the second direction.

The third doped region is disposed in the epitaxial layer and extends from the surface of the epitaxial layer facing away from the substrate along the first direction. The third doped region is arranged around the first doped region, and the third doped region is of the second conductivity type.

The gate structure is at least partially disposed above the third sub-doped region and extends above the fourth sub-doped region and the fifth sub-doped region. The gate structure comprises a gate oxide layer and a first conductive electrode. The gate oxide layer is located between the first conductive electrode and the epitaxial layer, and the first conductive electrode is used to access an output end of a first voltage.

The second conductive electrode is connected to the fourth sub-doped region in ohmic contact and used to be grounded.

The third conductive electrode is connected to the fifth sub-doped region in ohmic contact, and the third conductive electrode is used to access an output end of the second voltage.

According to some embodiments, a semiconductor wafer includes: multiple semiconductor device regions and multiple monitoring regions.

A semiconductor device in each of the multiple semiconductor device regions is a planar gate structure power device.

The multiple monitoring regions are provided with at least one semiconductor test device as in the above solution used to test a channel mobility of the planar gate structure power device.

### BRIEF DESCRIPTION OF DRAWINGS

In order to more clearly illustrate the technical solutions in the embodiments of the disclosure, the accompanying drawings required for describing the embodiments will be briefly introduced below. Obviously, the accompanying drawings in the following description show only some embodiments of the disclosure, and a person of ordinary skill in the art may obtain other accompanying drawings based on these drawings without creative efforts, wherein:

FIG. 1 illustrates a schematic process diagram of forming a channel of a power device by adopting a self-aligned scheme in the related art.

FIG. 2 illustrates a schematic structural diagram of a planar gate structure power device in the related art.

FIG. 3 illustrates a schematic structural diagram of a test device used to characterize a mobility of the planar gate structure power device in the related art.

FIG. 4 illustrates a schematic structural diagram of a semiconductor wafer according to an embodiment of the disclosure.

FIG. 5 illustrates a schematic structural block diagram of an enlarged region A in FIG. 4.

FIG. 6 illustrates a schematic structural diagram of a semiconductor test device according to an embodiment of the disclosure.

FIG. 7 illustrates an equivalent circuit diagram of an embodiment of the semiconductor test device according to the embodiment of the disclosure.

FIG. 8 illustrates a schematic diagram of a partial intermediate product after a second step of a preparation method of the semiconductor test device according to the disclosure.

FIG. 9 illustrates a schematic process diagram of forming a channel of the semiconductor test device using a self-aligned scheme according to the disclosure.

FIG. 10 illustrates a schematic diagram of a partial intermediate product after a fourth step of the preparation method of the semiconductor test device according to the disclosure.

FIG. 11 illustrates a schematic diagram of a partial intermediate product after a sixth step of the preparation method of the semiconductor test device according to the disclosure.

FIG. 12 illustrates a schematic diagram of a partial intermediate product after a ninth step of the preparation method of the semiconductor test device according to the disclosure.

FIG. 13 illustrates a schematic diagram of a partial intermediate product after an eleventh step of the preparation method of the semiconductor test device according to the disclosure.

FIG. 14 illustrates another schematic structural diagram of the semiconductor test device according to the embodiment of the disclosure.

### DETAILED DESCRIPTION OF EMBODIMENTS

The technical solutions in the embodiments of the disclosure will be clearly and completely described below with reference to the accompanying drawings in the embodiments of the disclosure. It is apparent that the described embodiments are only part of the embodiments of the disclosure, rather than all of them. All other embodiments obtained by a person of ordinary skill in the art based on the embodiments of the disclosure without creative efforts shall fall within the scope of protection of the disclosure.

The terms “first,” “second,” and “third” in the disclosure are used for descriptive purposes only and are not to be construed as indicating or implying relative importance or implicitly specifying the quantity of the indicated technical features. Thus, features defined with “first,” “second,” or “third” may explicitly or implicitly include at least one such feature. In the description of the disclosure, the term “a plurality of” means at least two, such as two, three, etc., unless explicitly specified otherwise. All directional indications (such as up, down, left, right, front, back, etc.) in the embodiments of the disclosure are used only to explain the relative positional relationships, movements, etc., between components in a specific posture (as shown in the accompanying drawings). If the specific posture changes, the directional indications shall change accordingly. In addition, the terms “comprise” and “have,” as well as any variations thereof, are intended to cover non-exclusive inclusion. For example, a process, method, system, product, or device that includes a series of steps or units is not limited to the listed steps or units but may optionally include steps or units not listed or other steps or units inherent to such processes, methods, products, or devices.

Mention of “an embodiment” herein means that a specific feature, structure, or characteristic described in connection with the embodiment may be included in at least one embodiment of the disclosure. The appearance of this phrase in various places in the specification does not necessarily refer to the same embodiment, nor is it an independent or alternative embodiment mutually exclusive with other embodiments. Those skilled in the art explicitly and implicitly understand that the embodiments described herein may be combined with other embodiments.

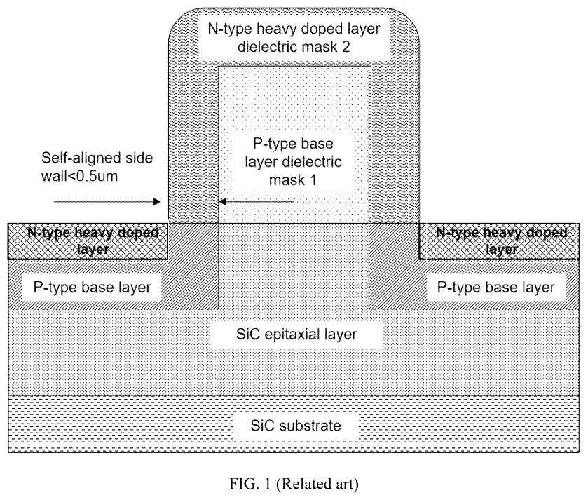

Referring to FIG. 1, dielectric mask 1 is an implantation mask for a P-type base layer, and dielectric mask 2 with a thickness less than 0.5 micrometers (μm) can be directly grown without removing the dielectric mask 1 after implantation. After etching, only the dielectric mask 1 and the dielectric mask 2 on a side wall of the dielectric mask 1 remain, the remaining dielectric mask 2 is removed, and then N-type heavy doping implantation is carried out, so that a channel is automatically formed at a position where the N-type heavy doping is not implanted in the P-type base layer, thereby realizing the self-alignment between the P-type base layer and a N-type heavy doped layer, so as to obtain a channel below 0.5 μm. This technology has been widely used in the power device industry, which promotes the reduction of cell size. However, there is a problem in this technology: the channel mobility of power devices cannot be effectively characterized.

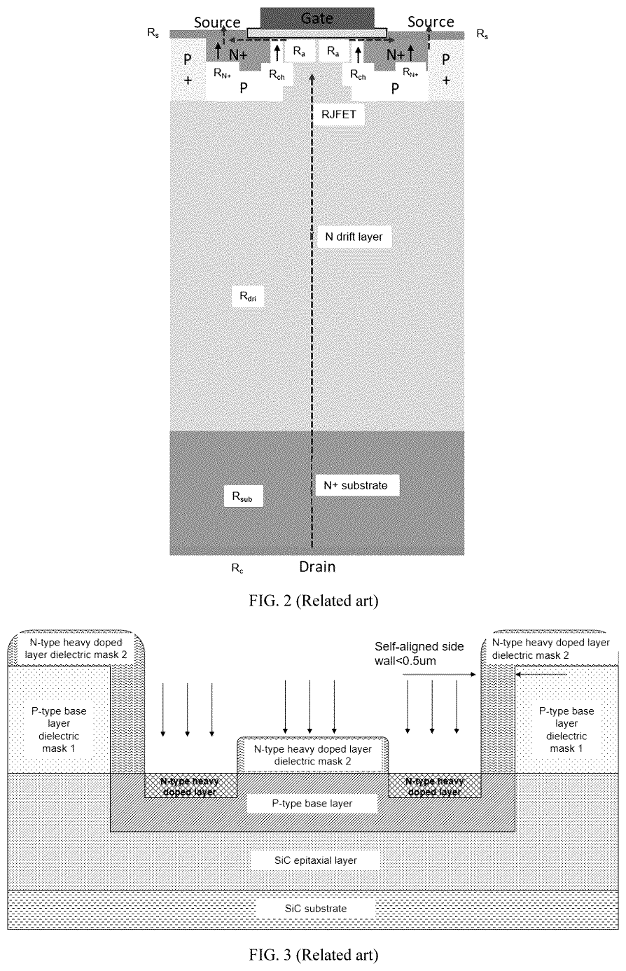

A planar gate structure power device is taken as an example to illustrate. Referring to FIG. 2, source and drain electrodes are on upper and lower sides of the device respectively. The vertical structure leads to parasitic resistances such as ohmic contact resistance R_{C}, N-type heavy doped layer resistance R_{N+}, drift region (epitaxial layer) resistance R_{dri}, substrate resistance R_{sub}, etc., especially the drift region resistance R_{dri} will reduce the real current.

Accurately characterizing the mobility of silicon carbide metal-oxide-semiconductor field-effect transistor (SiC MOSFET) is an important technology to evaluate the gate oxide process and monitor the product stability. Generally, Id-Vgs formula is used to evaluate the process level based on the field-effect mobility. In order to eliminate the influence of other parasitic resistances on the current Id, it is necessary to ensure that the test device resistance only contains the channel resistance, or the channel resistance accounts for the vast majority. Therefore, the test device used to characterize the mobility of the power devices generally adopts LDMOSFET power devices. Referring to FIG. 3, in the actual wafer fabrication, the P-type base layer and N-type heavy doped layer in the LDMOSFET test device are consistent with those in the vertical double-diffused metal-oxide-semiconductor field-effect transistor (VDMOSFET) power device, so as to ensure process consistency and realize accurate evaluation.

The Id-Vgs formula (1) is as follows:

$$μ = \frac{{g}_{m} L}{{WC}_{ox} {V}_{ds}} = \frac{\partial {I}_{ds}}{\partial {V}_{gs}} \times \frac{L}{{WC}_{ox} {V}_{ds}} . \qquad ( 1 )$$

In the formula, W is a width of a gate electrode, L is a length of the gate electrode, V_{ds} is a voltage between the drain electrode and the source electrode, V_{gs} is a voltage between the gate electrode and the source electrode, Cₒₓ is a capacitance of a gate dielectric (usually silicon dioxide, abbreviated as SiO₂) per unit area, las is a channel current, and gₘ is a derivative of the channel current I_{ds} to the voltage V_{gs}, that is, the transconductance.

This formula assumes that the voltage V_{ds} from the source electrode to the drain electrode is borne by the channel resistance R_{ch}. However, in fact, the whole current path further includes the ohmic contact resistance R_{C} and the N-type heavy doping resistance R_{N+}. In this way, the obtained current I_{ds} is smaller than the real channel current, and the channel mobility u obtained by solution is smaller than the real mobility. With the increase of the voltage V_{gs}, the channel resistance R_{ch} further decreases, and the influence of the parasitic resistances on the channel current I_{ds} increases. The channel current I_{ds} deviates from the linear relationship with the voltage V_{gs}, and the transconductance gₘ decreases. Therefore, when solving the mobility, the maximum transconductance g_{m.max} of the current I_{ds} to the voltage V_{gs} is generally taken as the solution. Based on this formula, the mobility of the planar gate MOSFET is measured, and the result will be much smaller than the real value.

Combined with FIG. 1 and FIG. 2, as the cell size of the VDMOSFET is reduced, the channel length needs to be continuously reduced, which requires the thickness of the dielectric mask 2 to be continuously reduced. When the thickness of the dielectric mask 2 is less than 0.45 μm, the N-type heavy doping implantation cannot be effectively blocked, which will lead to the inversion of the P-type base layer into the N-type doped layer. The VDMOSFET does not need to worry about this problem. It only needs to ensure that N-type impurities are not injected into the position of the sidewall dielectric mask 2, the dielectric mask 2 at this position is generated close to the sidewall of the dielectric mask 1, and the thickness of blocking the injection is determined by the height of the dielectric mask 1, which can effectively block the N-type heavy doped injection. However, in FIG. 3, in order to accurately characterize the channel mobility of the LDMOSFET, its channel length (usually greater than 5 μm, with a typical value of 100 μm) is much greater than 0.5 μm, which leads to the fact that the thickness of the dielectric mask 2 on most P-type base layers of the LDMOSFET cannot effectively block the implantation, and most P-type base layers will turn into N-type doped layers, which will aggravate the short channel effect (make the test mobility higher) and even become depletion devices.

In order to realize the effective compatibility between the LDMOSFET process and VDMOSFET channel self-aligned process, and ensure that the N-type implantation mask of the LDMOSFET can block implantation and accurately characterize mobility, the disclosure proposes a semiconductor test device, which can keep the channel length of the semiconductor test device more than 100 μm and ensure that the channel resistance occupies the main part.

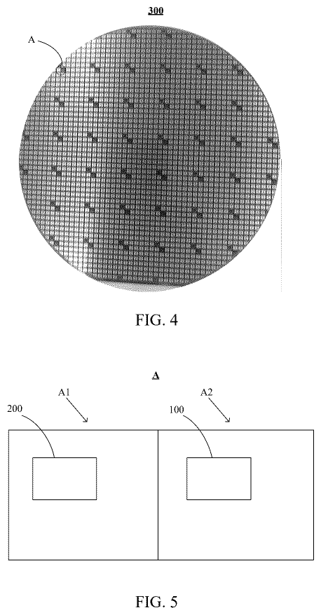

Referring to FIG. 4 and FIG. 5, the semiconductor test device 100 for characterizing the mobility of the planar gate MOSFET proposed by the disclosure can be integrated with the planar gate MOSFET in the same semiconductor wafer 300.

The semiconductor wafer 300 includes multiple semiconductor device regions A1 and multiple monitoring regions A2. A semiconductor device is arranged in the semiconductor device region A1, and the semiconductor device is a planar gate structure power device 200. At least one semiconductor test device 100 for testing the channel mobility of the planar gate structure power device 200 is arranged in the monitoring region A2.

Specifically, in the semiconductor device region A1 as illustrated in FIG. 5, only one semiconductor device is exemplarily disclosed, and in the monitoring region A2, only one semiconductor test device 100 is exemplarily disclosed. In other embodiments, multiple semiconductor devices may be included in the semiconductor device region A1, and the monitoring region A2 may include multiple semiconductor test devices 100.

The semiconductor wafer 300 according to the disclosure characterizes the mobility of the planar gate structure power device 200 by testing the channel mobility of the semiconductor test device 100.

In an embodiment, the planar gate structure power device 200 can be the same as the related art (such as the exemplary device shown in FIG. 2). Although the disclosure takes the planar gate MOSFET as an example, it is also applicable to other planar gate structure power devices (such as insulated-gate bipolar transistor abbreviated as IGBT, super junction MOSFET, etc.), and the materials can be SiC, silicon abbreviated as Si, gallium oxide abbreviated as Ga₂O₃, gallium nitride abbreviated as GaN, diamond, etc.

The semiconductor test device 100 of the disclosure adopts a wafer structure and manufacturing process compatible with the actual wafer fabrication, and can be integrated in a process control monitoring region of the layout for on-line monitoring of process capability and device real mobility.

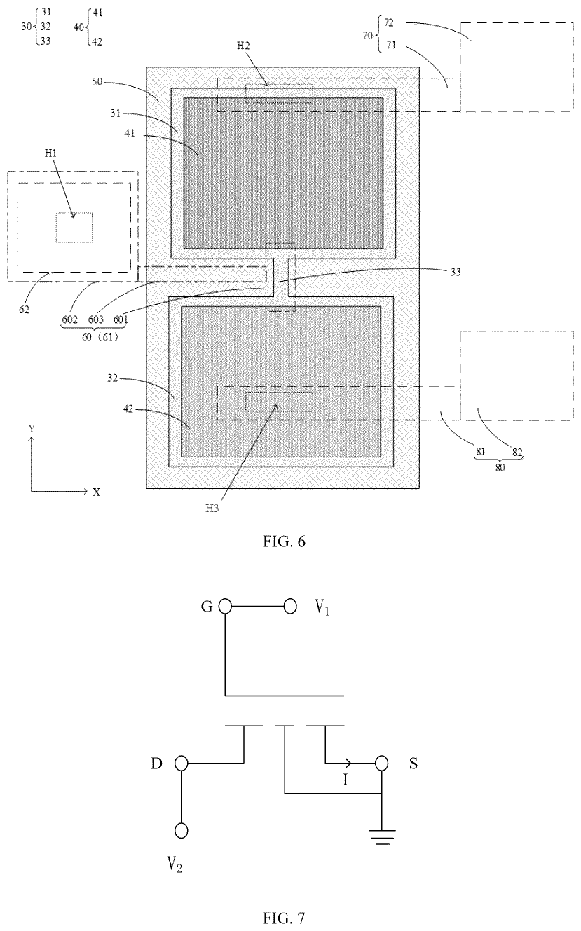

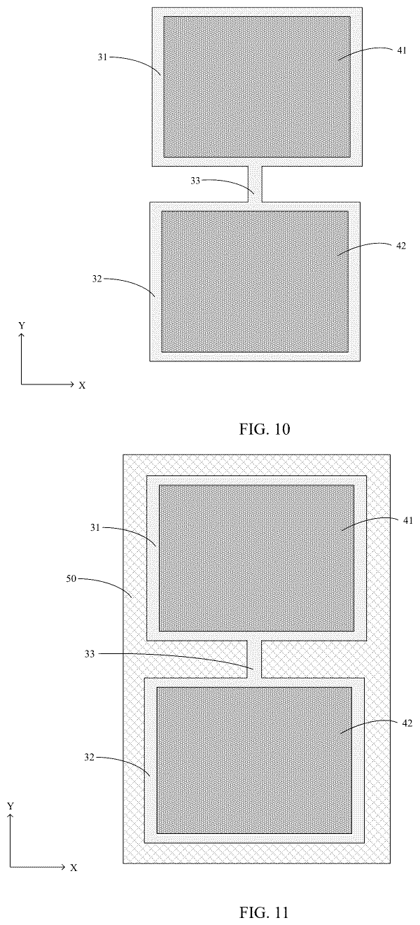

Referring to FIG. 6, FIG. 7 and FIG. 9, the semiconductor test device 100 mainly includes features as follows.

The semiconductor test device 100 includes a substrate 10, an epitaxial layer 20 and a second doped region 40, which are of a first conductivity type. The semiconductor test device 100 further includes a first doped region 30 and a third doped region 50, which are of a second conductivity type. The semiconductor test device 100 further includes a gate structure 60 used to access an output end of a first voltage, a second conductive electrode 70 used to be grounded, and a third conductive electrode 80 used to access an output end of a second voltage.

Specifically, one of the first conductivity type and the second conductivity type is a P-type conductivity type, and the other of the first conductivity type and the second conductivity type is an N-type conductivity type. In the embodiment of the disclosure, the first conductivity type is the N-type conductivity type and the second conductivity type is the P-type conductivity type.

An ion doping concentration of the second doped region 40 is greater than that of the epitaxial layer 20, and the second doped region can be understood as an N-type heavy doped layer. An ion doping concentration of the third doped region 50 is greater than that of the first doped region 30, which can be understood as a P-type base region and the third doped region 50 as a P-type heavy doped region.

The first doped region 30 includes a first sub-doped region 31, a second sub-doped region 32 and a third sub-doped region 33. The first sub-doped region 31, the second sub-doped region 32 and the third sub-doped region 33 are all arranged in the epitaxial layer 20 and extend along a first direction Z from a surface of the epitaxial layer 20 facing away from the substrate 10. The first direction Z is the direction in which the epitaxial layer 20 faces towards the substrate 10. The first sub-doped region 31 and the second sub-doped region 32 are spaced along a second direction Y, the third sub-doped region 33 is connected the first sub-doped region 31 and the second sub-doped region 32, and the second direction Y is perpendicular to the first direction Z.

The second doped region 40 includes a fourth sub-doped region 41 and a fifth sub-doped region 42. The fourth sub-doped region 41 is arranged in the first sub-doped region 31 and has a first spacing distance from an edge of the first sub-doped region 31. The fifth sub-doped region 42 is disposed in the second sub-doped region 32 and has a second spacing distance from an edge of the second sub-doped region 32. The fourth sub-doped region 41 and the fifth sub-doped region 42 extend from the surface of the epitaxial layer 20 facing away from the substrate 10 along the first direction Z. The first spacing distance is the same as the second spacing distance, and a width of the third sub-doped region 33 is greater than or equal to the first spacing distance and less than or equal to twice the first spacing distance. A width direction X of the third sub-doped region 33 is perpendicular to the first direction Z and the second direction Y.

The third doped region 50 is located in the epitaxial layer 20, extends from a surface of the epitaxial layer to the first direction Z, and is arranged around the first doped region 30.

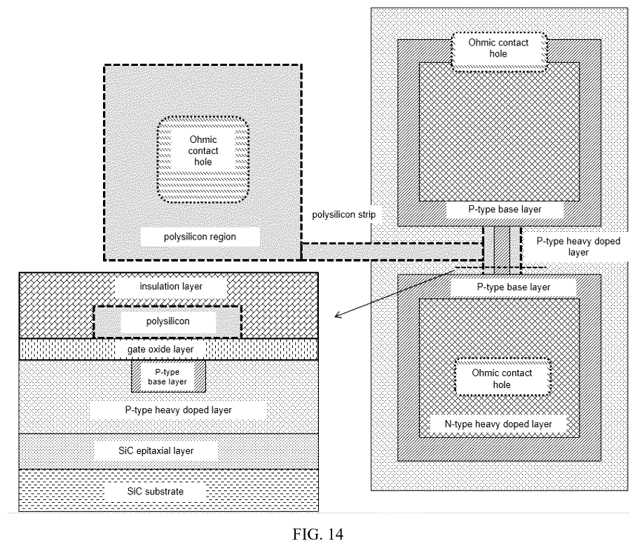

The gate structure 60 is at least partially disposed above the third sub-doped region 33 and extends above the fourth sub-doped region 41 and the fifth sub-doped region 42. As shown in FIG. 14, the gate structure 60 includes a gate oxide layer and a first conductive electrode 61. The gate oxide layer is located between the first conductive electrode 61 and the epitaxial layer 20, and the first conductive electrode 61 is used to access the output end of the first voltage.

The second conductive electrode 70 is connected to the fourth sub-doped region 41 in ohmic contact and is used to be grounded. The third conductive electrode 80 is connected to the fifth sub-doped region 42 in ohmic contact, and the third conductive electrode 80 is used to access the output end of the second voltage.

Under a test condition, the first voltage and the second voltage are configured to turn on the semiconductor test device 100 (i.e., the semiconductor test device 100 in a conduction state), thereby calculating the mobility of the semiconductor test device 100 to characterize the mobility of the planar gate structure power device 200. The first voltage may be equivalent to a voltage V_{gs} between a source electrode and a gate electrode of a normal power device, and the second voltage may be equivalent to a voltage V_{ds} between the source electrode and a drain electrode of the normal power device.

In an embodiment, under the test condition, the first voltage is configured to be greater than an absolute value of a threshold voltage of the gate structure 60, and the second voltage is configured to be greater than 0 volt (V) and less than 0.5 V, so that the semiconductor test device 100 is in a conduction state based on the first voltage and the second voltage.

Referring to FIG. 7, point G represents the first conductive electrode 61, and the point G is connected to the output end of the first voltage V₁, point D represents the third conductive electrode 80, and the point D is connected to the output end of the second voltage V₂, point S represents the second conductive electrode 70, and the point S is grounded. Under the test condition, the first voltage V₁ is configured to be greater than the threshold voltage of the gate structure 60, and the second voltage V₂ is configured to be greater than 0 V, so that the semiconductor test device 100 is in the conduction state based on the first voltage V₁ and the second voltage V₂, and the mobility of the semiconductor test device 100 is calculated based on the test current I obtained at the point S to characterize the mobility of the planar gate structure power device 200.

In the structure of the semiconductor test device 100 according to the embodiment of the disclosure, the gate structure 60 used to access the output end of the first voltage is at least partially arranged above the third sub-doped region 33 and extends above the fourth sub-doped region 41 and the fifth sub-doped region 42. The second conductive electrode 70 used to be grounded is connected to the fourth sub-doped region 41 in ohmic contact, and the third conductive electrode 80 used to access the output end of the second voltage is connected to the fifth sub-doped region 42 in ohmic contact, so that the current path flows to the fourth sub-doped region 41 along the third sub-doped region 33 via the fifth sub-doped region 42, which is parallel to an extension direction (i.e., the second direction Y) of the gate structure 60. In this way, the channel length of the semiconductor test device can be arbitrarily increased in the second direction Y to ensure that the channel resistance occupies the main part, and the accurate characterization of the channel mobility is realized.

In addition, the first spacing distance is set to be the same as the second spacing distance, and the width of the third sub-doped region 33 is greater than or equal to the first spacing distance and less than or equal to twice the first spacing distance. Combined with FIG. 9, when the dielectric mask 2 for doping the second doped region 40 is deposited, the dielectric mask 2 on two side walls above the third sub-doped region 33 are automatically closed. The thickness of the dielectric mask 2 on the whole channel region (a part of the first sub-doped region 31, a part of the second sub-doped region 32, and the third sub-doped region 33) is greater than that of the dielectric mask 1. Thus, the N-type heavy doping can be effectively blocked from being implanted into the channel region and the device can be prevented from being transformed into a depletion device, and the scheme realizes perfect compatibility of the self-aligned process.

Further, when the first spacing distance and the second spacing distance are less than 0.5 μm, the width of the third sub-doped region 33 (corresponding to the width of the channel region) is less than 1 μm. This structure is suitable for miniature power devices of any size, and solves the problem that the self-aligned process of the VDMOSFET power device is not compatible with the LDMOSFET test device.

In some embodiments, the width of the third sub-doped region 33 can be 1 time, 1.5 times or 2 times of the spacing distance (for example, when it is 2 times, the dielectric mask 2 on both sides is just closed, and the thickness of the dielectric mask 2 is consistent with the height of the dielectric mask 1). The first sub-doped region 31 and the second sub-doped region 32 can be symmetrically arranged (making the first doped region 30 in an I-shaped or H-shaped configuration). An outer contour of that third doped region 50 can be rectangular.

In some embodiments, the gate structure 60 includes a first connection region 601, a second connection region 602, and a third connection region 603. The first connection region 601 is at least partially disposed above the third sub-doped region 33 and extends above the fourth sub-doped region 41 and the fifth sub-doped region 42. The second connection region 602 is located on the epitaxial layer 20 and outside the third doped region 50. The third connection region 603 is at least partially disposed above the third doped region 50, an end of the third connection region 603 is connected to the first connection region 601, and the other end of the third connection region 603 extends towards the region outside the third doped region 50 and is connected to the second connection region 602.

The first doped region 30 below the first connection region 601 is the channel region of the semiconductor test device 100. In this embodiment, the width of the first connection region 601 is greater than that of the third sub-doped region 33, so as to ensure that the entire third sub-doped region 33 can be used as the channel region.

As shown in FIG. 14, the semiconductor test device 100 further includes an insulation layer covering the surface of the epitaxial layer 20 and the gate structure 60. Referring to FIG. 6, the insulation layer is defined with a first through hole H1 (i.e., ohmic contact hole), a second through hole H2 (i.e., ohmic contact hole), and a third through hole H3 (i.e., ohmic contact hole) spaced.

The first through hole H1 is arranged corresponding to the second connection region 602. The semiconductor test device 100 further includes a conductive metal layer 62, and the conductive metal layer 62 is connected to the first conductive electrode 61 in ohmic contact through the first through hole H1. In an embodiment, as shown in FIG. 6, the first conductive electrode 61 is polysilicon, and the conductive metal layer 62 is connected to the polysilicon in ohmic contact through the first through hole H1, and the conductive metal layer 62 serves as a gate metal plate of the semiconductor test device 100.

Specifically, the second through hole H2 is arranged corresponding to a part of the first sub-doped region 31, a part of the fourth sub-doped region 41 and a part of the third doped region 50. The second conductive electrode 70 is disposed on the insulation layer and is connected to the fourth sub-doped region 41 in ohmic contact through the second through hole H2. As shown in FIG. 6, the second conductive electrode 70 includes a first metal connection strip 71 and a first metal connection plate 72 which are electrically connected. The first metal connection strip 71 is connected to the fourth sub-doped region 41 in ohmic contact through the second through hole H2, and the second metal connection plate 72 is used to be grounded as a source metal plate of the device.

The third through hole H3 is arranged corresponding to the fifth sub-doped region 42. The third conductive electrode 80 is disposed on the insulation layer and connected to the fifth sub-doped region 42 in ohmic contact through the third through hole H3. As shown in FIG. 6, the third conductive electrode 80 includes a second metal connection strip 81 and a second metal connection plate 82 which are electrically connected. The second metal connection strip 81 is connected to the fifth sub-doped region 42 in ohmic contact through the third through hole H3, and the second metal connection plate 82 is used to connect the output end of the second voltage as a drain metal plate of the device.

In order to realize the insulation between electrodes of the test device, as shown in FIG. 6, the second conductive electrode 70, the third conductive electrode 80 and the conductive metal layer 62 are designed at intervals.

In some embodiments, the resistivity of the second conductive electrode 70, the third conductive electrode 80 and the conductive metal layer 62 are all less than 1×10⁻⁵ ohm-centimeter (Ω·cm) to reduce the influence of resistance on mobility.

Specifically, the materials of the second conductive electrode 70, the third conductive electrode 80 and the ohmic contact electrode between the conductive metal layer 62 and the underlying semiconductor material include but are not limited to Ti, Ni, Ti/N, TiN/Ni, Ta/Ni, Ta/TiN/Ni, Ti/W, etc.

In the semiconductor test device 100 provided by the embodiment of the disclosure, the substrate and epitaxial layer are consistent with the actual wafer, and there is no special requirement. The current path does not pass through that epitaxial layer and the substrate, thereby eliminating the influence of parasitic resistance and accurately characterizing the mobility. The problem of process compatibility between VDMOSFET and LDMOSFET test devices is solved.

The embodiment of the disclosure also provides a preparation method of the semiconductor test device 100, taking the wafer fabrication of the SiC MOSFET as an example. The details are as follows.

In the first step, a 1.5 μm dielectric mask 1 is grown on a SiC epitaxial layer 20 for the implantation mask of a P-type base layer.

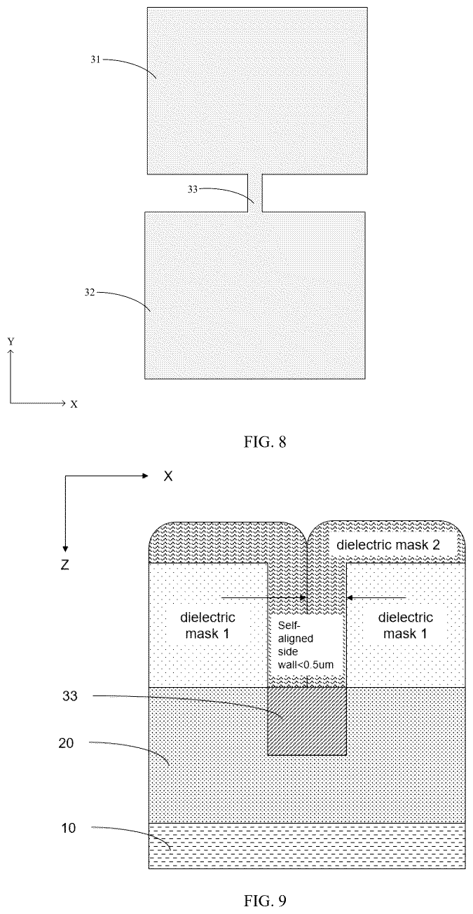

In the second step, I-shaped P-type base layer implantation regions are defined on the dielectric mask 1 through photolithography and etching process. As shown in FIG. 8, implantation regions (the first sub-doped region 31 and the second sub-doped region 32) on upper and lower sides of the I-shaped P-type base layer implantation region are squares of 100 μm*100 μm, and the implantation region in the middle region (the third sub-doped region 33) is 0.9 μm*50 μm.

In the third step, after A1 element is implanted to form the P-type base layer, a 0.45 μm dielectric mask 2 is deposited to form the channel (0.45 μm) of the VDMOSFET power device. As shown in FIG. 9, the 0.9 μm*50 μm channel in the LDMOSFET mobility test device is completely closed.

In the fourth step, the N-type heavy doped implantation region is defined by photolithography and etching. As shown in FIG. 10, the N-type heavy doped implantation region is located in the upper and lower sides of the P-type base layer (the fourth sub-doped region 41 and the fifth sub-doped region 42), and the boundary is 0.45 μm away from the P-type base layer, which is automatically defined by the self-aligned dielectric mask 2. The channel of the P-type implantation region is shielded by the dielectric mask 2 and does not need to be etched.

In the fifth step, the dielectric mask 1 and the dielectric mask 2 are removed, and a dielectric mask is re-grown.

In the sixth step, the re-grown dielectric mask is photoetched, and the P-type heavy doped implantation region (third doped region 50) is defined by the etching process, and the third doped region 50 is arranged around the first doped region 30, so as to wrap the P-type base layer. Referring to FIG. 11, the P-type heavy doped implantation region in the upper and lower regions of the I-shaped P-type base layer implantation regions is 140 μm*25 μm, so that a rectangle with an implantation area of 140 μm*300 μm is obtained by adding the P-type base layer and the P-type heavy doped implantation region. After high temperature, the impurities in each doped region are electrically activated.

In the seventh step, after high-temperature oxidation, a layer of 50 nanometers (nm) SiO₂ is grown on the surface of SiC as a gate oxide layer of LDMOSFET.

In the eighth step, a layer of N-type heavy doped polysilicon is deposited on the gate oxide layer with a thickness of 5000 Ångström (Å).

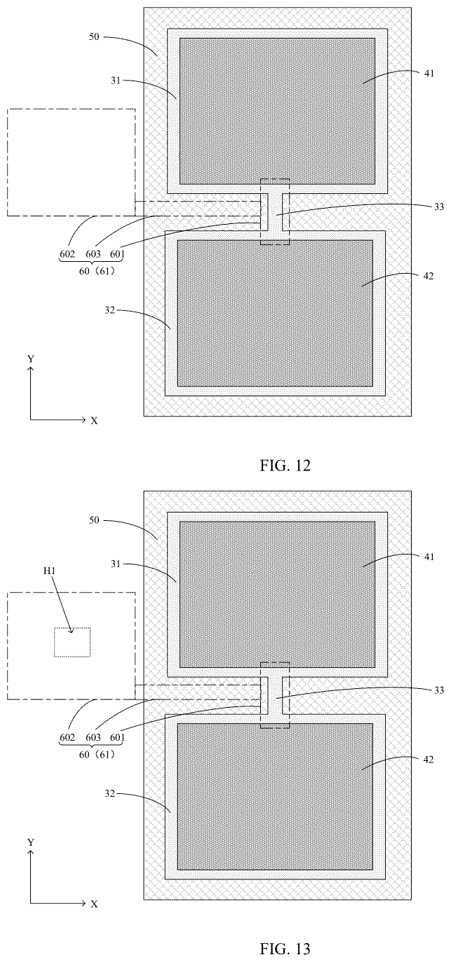

In the ninth step, referring to FIG. 12, after photolithography and etching, a polysilicon gate electrode (i.e., the gate structure 60, including first conductive electrode 61 and the gate oxide layer) is formed. This polysilicon gate electrode covers the middle channel region of the I-shaped P-type base layer (corresponding to the first connection region 601 of the gate structure 60), with a size of 1.5 μm*55 μm, extends to the left along the I-shaped horizontal line direction and is connected to the large polysilicon region on the left side (corresponding to the second connection region 602 of the gate structure 60), in which the extension strip is rectangular (corresponding to the third connection region 603 of the gate structure 60) with an area of 170 μm*30 μm, and the large polysilicon region on the left side is square with an area of 200 μm*200 μm.

In the tenth step, an interlayer dielectric layer is grown as an insulation layer to cover the whole area.

In the eleventh step, the interlayer dielectric layer is etched by photolithography, and the openings (the first through hole H1, the second through hole H2 and the third through hole H3) of the ohmic contact region of the source electrode, the ohmic contact region of the drain electrode, and the ohmic contact region of the gate electrode. As shown in FIG. 13, FIG. 13 illustrates a schematic diagram of a partial intermediate product after the eleventh step of the preparation method of the semiconductor test device according to the disclosure. Specifically, the ohmic contact region of the source electrode is located above the I-shaped P-type base layer, and the bottom is covered with a part of the P-type heavy doped layer and the N-type heavy doped layer, with an area of 80 μm*30 μm. The ohmic contact region of the drain electrode is located below the I-shaped P-type base layer, and the bottom is covered with an N-type heavy doped layer, with an area of 80 μm*30 μm. The ohmic contact region of the gate electrode is located in the center of the large square polysilicon area on the left side, with an area of 80 μm*80 μm.

In the twelfth step, a layer of nickel with a thickness of 1000 Å is sputtered. After annealing, nickel silicide is formed respectively with the SiC of the P-type heavy doped layer and the N-type heavy doped layer, and with the polysilicon in the ohmic contact region of the gate electrode. Then, the nickel that has not formed nickel silicide is removed using a nickel metal removal solution.

In the thirteenth step, a layer of aluminum-copper (Al—Cu) alloy with a thickness of 4 μm is sputtered, and a source electrode metal (i.e., the second conductive electrode 70), a drain electrode metal (i.e., the third conductive electrode 80) and a gate electrode metal (i.e., the conductive metal layer 62) are formed after photolithography and etching. As shown in FIG. 6, FIG. 6 illustrates a schematic diagram of a partial intermediate product after the thirteenth step of the preparation method of the semiconductor test device according to the disclosure. Specifically, the source electrode metal covers the ohmic contact region of the source electrode and consists of a source electrode metal strip of 230 μm*50 μm and a square source electrode metal plate of 100 μm*100 μm. The drain electrode metal covers the ohmic contact region of the source electrode and consists of a drain electrode metal strip of 230 μm*50 μm and a square drain electrode metal plate of 100 μm*100 μm. The gate electrode metal covers the ohmic contact region of the gate electrode to form a square gate electrode metal plate of 100 μm*100 μm.

Through the above steps, the semiconductor test device 100 is formed.

The foregoing are only specific implementations of the disclosure and are not intended to limit the scope of the patent of the disclosure. Any equivalent structures or equivalent process transformations made based on the description and drawings of the disclosure, or any direct or indirect applications in other related technical fields, shall similarly fall within the scope of patent protection of the disclosure.

What is claimed is:

1. A semiconductor test device, comprising:
a substrate;
an epitaxial layer, arranged on a surface of the substrate, wherein the substrate and the epitaxial layer are of a first conductivity type;
a first doped region, comprising a first sub-doped region, a second sub-doped region and a third sub-doped region, wherein the first sub-doped region, the second sub-doped region and the third sub-doped region are all arranged in the epitaxial layer and extend from a surface of the epitaxial layer facing away from the substrate along a first direction; the first direction is a direction of the epitaxial layer facing towards the substrate; the first doped region is of a second conductivity type; the first sub-doped region and the second sub-doped region are spaced along a second direction, the third sub-doped region is connected to the first sub-doped region and the second sub-doped region, and the second direction is perpendicular to the first direction;
a second doped region, comprising a fourth sub-doped region and a fifth sub-doped region, wherein the fourth sub-doped region is arranged in the first sub-doped region and has a first spacing distance from an edge of the first sub-doped region; the fifth sub-doped region is arranged in the second sub-doped region and has a second spacing distance from an edge of the second sub-doped region; the fourth sub-doped region and the fifth sub-doped region extend from the epitaxial layer facing away from the surface of the substrate along the first direction; the second doped region is of the first conductivity type; the first spacing distance is the same as the second spacing distance; a width of the third sub-doped region is greater than or equal to the first spacing distance and less than or equal to twice the first spacing distance; and a width direction of the third sub-doped region is perpendicular to the first direction and the second direction;
a third doped region, disposed in the epitaxial layer and extending from the surface of the epitaxial layer facing away from the substrate along the first direction; wherein the third doped region is arranged around the first doped region; and the third doped region is of the second conductivity type;
a gate structure, at least partially disposed above the third sub-doped region and extending above the fourth sub-doped region and the fifth sub-doped region; wherein the gate structure comprises a first conductive electrode, and the first conductive electrode is configured to access an output end of a first voltage;
a second conductive electrode, connected to the fourth sub-doped region in ohmic contact, and configured to be grounded; and
a third conductive electrode, connected to the fifth sub-doped region in ohmic contact, and the third conductive electrode is configured to access an output end of a second voltage.

2. The semiconductor test device as claimed in claim 1, wherein the width of the third sub-doped region is equal to twice the first spacing distance.

3. The semiconductor test device as claimed in claim 1, wherein the first sub-doped region and the second sub-doped region are symmetrically arranged.

4. The semiconductor test device as claimed in claim 1, wherein the gate structure comprises a first connection region, a second connection region, and a third connection region; the first connection region is at least partially arranged above the third sub-doped region and extends above the fourth sub-doped region and the fifth sub-doped region; the second connection region is arranged on the epitaxial layer and located outside the third doped region; the third connection region is at least partially arranged above the third doped region, and an end of the third connection region is connected to the first connection region, and another end of the third connection region extends towards a region outside the third doped region and is connected to the second connection region.

5. The semiconductor test device as claimed in claim 4, wherein a width of the first connection region is greater than that of the third sub-doped region.

6. The semiconductor test device as claimed in claim 4, further comprising:
an insulation layer, covering the surface of the epitaxial layer and the gate structure; wherein the insulation layer is defined with a first through hole, a second through hole and a third through hole spaced; the first through hole is arranged corresponding to the second connection region; the second through hole is arranged corresponding to a part of the first sub-doped region, a part of the fourth sub-doped region and a part of the third doped region; and the third through hole is arranged corresponding to the second sub-doped region;
wherein the second conductive electrode is connected to the fourth sub-doped region in ohmic contact through the second through hole; and the third conductive electrode is connected to the fifth sub-doped region in ohmic contact through the third through hole; and
wherein the semiconductor test device further comprises:
a conductive metal layer, electrically connected to the first conductive electrode through the first through hole.

7. The semiconductor test device as claimed in claim 1, wherein an ion doping concentration of the second doped region is greater than that of the epitaxial layer, and an ion doping concentration of the third doped region is greater than that of the first doped region.

8. The semiconductor test device as claimed in claim 1, wherein under a test condition, the first voltage is configured to be greater than an absolute value of a threshold voltage of the gate structure, and the second voltage is configured to be greater than 0 volt (V), so as to make the semiconductor test device be in a conduction state based on the first voltage and the second voltage to test a channel mobility of a planar gate structure power device.

9. The semiconductor test device as claimed in claim 1, wherein the first spacing distance and the second spacing distance are less than 0.5 micrometers (μm), and the width of the third sub-doped region is less than 1 μm.

10. The semiconductor test device as claimed in claim 6, wherein a resistivity of each of the second conductive electrode, the third conductive electrode and the conductive metal layer is less than 1×10⁻⁵ ohm-centimeter ((2·cm).

11. A semiconductor wafer, comprising:
a plurality of semiconductor device regions, wherein a semiconductor device in each of the plurality of semiconductor device regions is a planar gate structure power device; and
a plurality of monitoring regions, provided with at least one semiconductor test device as claimed in claim 1 configured to test a channel mobility of the planar gate structure power device.

12. The semiconductor wafer as claimed in claim 11, wherein the width of the third sub-doped region is equal to twice the first spacing distance.

13. The semiconductor wafer as claimed in claim 11, wherein the first sub-doped region and the second sub-doped region are symmetrically arranged.

14. The semiconductor wafer as claimed in claim 11, wherein the gate structure comprises a first connection region, a second connection region, and a third connection region; the first connection region is at least partially arranged above the third sub-doped region and extends above the fourth sub-doped region and the fifth sub-doped region; the second connection region is arranged on the epitaxial layer and located outside the third doped region; the third connection region is at least partially arranged above the third doped region, and an end of the third connection region is connected to the first connection region, and another end of the third connection region extends towards a region outside the third doped region and is connected to the second connection region.

15. The semiconductor wafer as claimed in claim 14, wherein a width of the first connection region is greater than that of the third sub-doped region.

16. The semiconductor wafer as claimed in claim 14, further comprising:
an insulation layer, covering the surface of the epitaxial layer and the gate structure; wherein the insulation layer is defined with a first through hole, a second through hole and a third through hole spaced; the first through hole is arranged corresponding to the second connection region; the second through hole is arranged corresponding to a part of the first sub-doped region, a part of the fourth sub-doped region and a part of the third doped region; and the third through hole is arranged corresponding to the second sub-doped region;
wherein the second conductive electrode is connected to the fourth sub-doped region in ohmic contact through the second through hole; and the third conductive electrode is connected to the fifth sub-doped region in ohmic contact through the third through hole; and
wherein the semiconductor test device further comprises:
a conductive metal layer, electrically connected to the first conductive electrode through the first through hole.

17. The semiconductor wafer as claimed in claim 11, wherein an ion doping concentration of the second doped region is greater than that of the epitaxial layer, and an ion doping concentration of the third doped region is greater than that of the first doped region.

18. The semiconductor wafer as claimed in claim 11, wherein under a test condition, the first voltage is configured to be greater than an absolute value of a threshold voltage of the gate structure, and the second voltage is configured to be greater than 0 V, so as to make the semiconductor test device be in a conduction state based on the first voltage and the second voltage to test the channel mobility of the planar gate structure power device.

19. The semiconductor wafer as claimed in claim 11, wherein the first spacing distance and the second spacing distance are less than 0.5 μm, and the width of the third sub-doped region is less than 1 μm.

20. The semiconductor wafer as claimed in claim 16, wherein a resistivity of each of the second conductive electrode, the third conductive electrode and the conductive metal layer is less than 1×10⁻⁵ Ω·cm.
